(19) United States
(12) Patent Application Publication
(10) Pub. No.: US 2014/0158196 A1
(43) Pub. Date: Jun. 12, 2014

(54) ELEMENT AND PHOTOVOLTAIC CELL

(71) Applicants: Yoshiaki Kurihara, Tsukuba-shi (JP); Masato Yoshida, Tsukuba-shi (JP); Takeshi Nojiri, Tsukuba-shi (JP); Yasushi Kurata, Tsukuba-shi (JP); Shuichiro Adachi, Tsukuba-shi (JP); Takahiko Kato, Hitachi-shi (JP)

(72) Inventors: Yoshiaki Kurihara, Tsukuba-shi (JP); Masato Yoshida, Tsukuba-shi (JP); Takeshi Nojiri, Tsukuba-shi (JP); Yasushi Kurata, Tsukuba-shi (JP); Shuichiro Adachi, Tsukuba-shi (JP); Takahiko Kato, Hitachi-shi (JP)

(21) Appl. No.: 14/233,383

(22) PCT Filed: Jul. 24, 2012
(86) PCT No.: PCT/JP2012/068721

§ 371 Date: Jan. 16, 2014

(30) Foreign Application Priority Data
Jul. 25, 2011 (JP) 2011-162598

(51) Int. Cl. H01L 31/0224

(52) U.S. Cl. CPC H01L 31/022425
USPC 136/256

(57) ABSTRACT

An element of the present invention includes a silicon substrate; an electrode which is provided on the silicon substrate and which is a sintered product of a paste composition for an electrode containing a phosphorus-containing copper alloy particle, a glass particle, a solvent and a resin; and a solder layer containing a flux, which is provided on the electrode.

### TECHNICAL FIELD

The present invention relates to an element and a photovoltaic cell.

### BACKGROUND ART

Generally, a photovoltaic cell is provided with a surface electrode, in which the wiring resistance or contact resistance of the surface electrode is related to a voltage loss associated with conversion efficiency, and further, the wiring width or shape has an influence on the amount of the incident sunlight.

The surface electrode of a photovoltaic cell is usually formed in the following manner. That is, a conductive composition is applied onto an n-type semiconductor layer, which is formed by thermally diffusing phosphorous or the like at a high temperature on the light-receiving surface side of a p-type silicon substrate, by screen printing or the like, and sintered at a high temperature of from 800° C. to 900° C., thereby forming a surface electrode. The conductive composition for forming the surface electrode includes conductive metal powders, glass particles, various additives, and the like.

As the conductive metal powders, silver powders are generally used, but the use of metal powders other than silver powders has been investigated for various reasons. For example, a conductive composition capable of forming an electrode for a photovoltaic cell, including silver and aluminum, is disclosed (see, for example, Japanese Patent Application Laid-Open (JP-A) No. 2006-313744). In addition, a composition for forming an electrode, including metal nanoparticles including silver and metal particles other than silver such as copper, is disclosed (see, for example, JP-A No. 2008-226816).

SUMMARY OF INVENTION

### Technical Problem

Silver, which is generally used to form an electrode, is a noble metal and, in view of problems regarding resources and also from the standpoint that the ore is expensive, proposals for a paste material which replaces the silver-containing conductive composition (silver-containing paste) are desirable. As a promising material for replacing silver, there is copper which is employed in semiconductor wiring materials. Copper is abundant as a resource and the cost of the metal is inexpensive, about as low as one hundredth the cost of silver. However, copper is a material susceptible to oxidation at high temperatures of 200° C. or higher. For example, for the composition for forming an electrode described in Patent Document 2, in a case in which the composition includes a copper as a conductive metal, it is necessary to conduct a special process in which the composition is sintered under an atmosphere of nitrogen or the like in order to form the electrode by sintering the composition. electrode by sintering the composition.

It is an object of the present invention to provide an element having an electrode which inhibits oxidation of copper during sintering and has a low resistivity, and a photovoltaic cell having the element.

### [Solution to Problems]

<1> An element including:
a silicon substrate:
an electrode that is provided on the silicon substrate and that is a sintered product of a paste composition for an electrode, the paste composition containing a phosphorus-containing copper alloy particle, a glass particle, a solvent and a resin; and
a solder layer containing a flux, the solder layer being provided on the electrode.

<2> The element according to the item <1>, in which the flux contains at least one selected from a halide, an inorganic acid, an organic acid or rosin.

<3> The element according to the item <2>, in which the halide is at least one selected from a chloride or a bromide.

<4> The element according to the item <2>, in which the inorganic acid contains at least one selected from a hydrochloric acid, hydrogen bromide acid, nitric acid, phosphoric acid or a boric acid.

<5> The element according to the item <2>, in winch the organic acid contains carboxylic acid.

<6> The element according to the item <5>, in which the carboxylic acid contains at least one selected from formic acid, acetic acid or oxalic acid.

<7> The element according to any one of the items <2> to <6>, in which die flux contains rosin at 5% by mass or higher,

<8> The element according to any one of the items <1> to <7>, in which the solder layer contains tin at 42% by mass or higher.

<9> The element for a photovoltaic cell comprising the element according to any one of the items <1> to <8>.
in which the silicon substrate includes an impurity diffusion layer to be pn-joined, and the electrode is provided on the impurity diffusion layer.

<10> A photovoltaic cell including
the element for a photovoltaic cell according to the item <9>; and
a tab wire connected to a solder layer of an electrode of the element.

### [Advantageous Effects of Invention]

By the present Invention, an element having an electrode that has reduced resistivity, due to inhibit oxidation of copper during sintering, and a photovoltaic cell having the element can be provided.

### BRIEF DESCRIPTION OF DRAWINGS

FIG. 1 is a cross-sectional view of the photovoltaic cell element of the present invention.

FIG. 2 is a plan view showing the light-receiving surface side of the photovoltaic cell element of the present invention.

FIG. 3 is a plan view showing the back surface side of the photovoltaic cell element of the present invention.

FIG. 4A is a perspective view showing the structure of the A-A cross-section of a back contact-type photovoltaic cell as an example of the photovoltaic cell element of the present invention.

FIG. 4B is a plan view showing the structure of the back surface side electrode of a back contact-type photovoltaic cell as an example of the photovoltaic cell element of the present invention.

### DESCRIPTION OF EMBODIMENTS

Embodiments of the present invention will now be described in detail below.

In the present specification, “from . . . to . . . ” denotes a range including each of the minimum value and the maximum value of the values described in this expression.

Furthermore, in the present specification, the term “process” denotes not only independent processes but also processes that cannot be clearly distinguished item other processes as long as a purpose is accomplished by the process.

Further, in the case in which the plurality of the materials corresponding to each compose nt are present in the composition, the amount of each component in the composition means a total amount of plural materials present in the composition unless otherwise specified.

### <Element>

An element of the present invention includes a silicon substrate, an electrode which is provided on the silicon substrate, and a solder layer which is provided on the electrode. The electrode is a sintered product of a paste composition for an electrode containing a phosphorus-containing copper alloy particle, a glass particle, a solvent and a resin. The solder layer contains a flux.

By forming the electrode using the phosphorus-containing copper alloy particle, an electrode having a low resistivity can be obtained. This is thought to be because phosphorus contained in the copper alloy particle functions as a reducing agent for copper oxide and the oxidation resistance of copper is thus increased. It is speculated that oxidation of copper is thereby suppressed, resulting in formation of an electrode having a low resistivity.

By allowing the solder layer provided on the electrode to contain a flux, the adhesion between the electrode and the solder layer improves, and further, the contact resistance of the interface between the electrode and the solder layer is reduced. This is thought to be because, by using the flux, a surface oxide film of the solder layer is removed, the wettability of the surface is improved, and the reformation of the surface oxide film is inhibited. It is speculated that, by this, the adhesion between the electrode and the solder layer is improved, and further, the contact resistance between the electrode and the solder layer is reduced.

The method of allowing the solder layer to contain a flux is not particularly limited, and examples thereof include a method in which a flux is applied on at least one surface of the electrode and the solder layer. By making the electrode and the solder layer be in contact with an pressed against each other to be further conducted a heat-treatment, thereby connecting the electrode and the solder layer.

The constituting members of the element of the present invention will now be described below.

### [Silicon Substrate]

The type of the silicon substrate in the present invention is not particularly restricted as long as it is a silicon substrate which is used in a mode where an electrode is formed using the electrode paste composition and a solder layer is formed on the electrode. Examples of such silicon substrate include silicon substrates having a pn junction that are used for the formation of a photovoltaic cell; and silicon substrates that are used in the manufacture of semiconductor devices other that a photovoltaic cell.

### [Electrode]

The electrode according to the present invention is a sintered product of a paste composition for an electrode containing a phosphorus-containing copper alloy particle, a glass particle, a solvent and a resin. A paste composition for an electrode used for forming an electrode will now be described in detail.

A paste composition for an electrode according to the present invention includes at lease one phosphorus-containing copper alloy particles; at lease one glass particles; at least one solvent; and at least one resin. By adopting such a constitution, owing to inhibiting the formation of an oxide film of copper even at a time of sintering, it is possible to form an electrode having a lower resistivity than cases in which copper particles are used.

### (Phosphorus-Containing Copper Alloy Particle)

A paste composition for an electrode according to the present invention includes at least one phosphorus-containing copper alloy particles.

The content of phosphorus in the phosphorus-containing copper alloy is preferably from 6% by mass to 8% by mass, more preferably from 6.3% by mass to 7.8% by mass, and still more preferably from 6.5% by mass to 7.5% by mass, from the standpoint of the oxidation resistance and the low resistivity. By setting the content of phosphorous in the phosphorous-containing copper alloy particles to 8% by mass or less, the low resistivity of a formed electrode can be more effectively attained and the productivity of the phosphorus-containing copper alloy particles is excellent. By setting the content of phosphorous in the phosphorous-containing copper alloy particles to 6% by mass or more, a more excellent oxidation resistance can be attained.

As the phosphorous-containing copper alloy for the phosphorous-containing copper alloy particles, a brazing material called copper phosphorous brazing (phosphorous concentration: usually about 7% by lass or less) is known. The copper phosphorous brazing is used as a copper to copper bonding agent. By using the phosphorous-containing copper alloy particle in the paste composition for an electrode according to the present invention, the reducing property of phosphorous against copper oxide can be utilized to form an electrode having excellent oxidation resistance and low resistivity. Furthermore, it becomes possible to sinter the electrode at a low temperature, and as a result, an effect of reducing a process cost can be attained.

The phosphorous-containing copper alloy particle is constituted by an alloy including copper and phosphorous, and it may further include other atoms. Examples of other atoms include Ag, Mn, Si, K, Na, Li, Ba, Sr, Ca, Mg, Be, Zn, Pb, Cd, Tl, V, Sn, Al, Zr, W, Mo, Ti, Cu, Ni, and Au.

The content of other atoms contained in the phosphorous-containing copper alloy particle may be, for example, 3% by mass or less in the phosphorous-containing copper alloy particle, and from the standpoint of the oxidation and the low resistivity, it is preferably 1% by mass or less.

The phosphorous-containing copper alloy particles may be used singly or in combination of two or more kinds thereof.

The particle diameter of the phosphorous-containing copper alloy particles is not particularly limited, and it is preferably from 0.4 μm to 10 μm, and more preferably from 1 μm to 7 μm in terms of a particle diameter when the cumulative weight is 50% (hereinafter abbreviate as “D50%” in some cases). By setting the particle diameter of the phosphorous-containing copper alloy particles to 0.4 μm or more, the oxidation resistance is improved more effectively. By setting the particle diameter of the phosphorous-containing copper alloy particles to 10 μm or less, the contact area at which the phosphorous-containing copper alloy particles contact each other in the electrode increases, whereby the resistivity of the formed electrode is reduced more effectively. The particle diameter of the phosphorous-containing copper alloy particle is measured by MICROTRAC particle size distribution analyzer (MT330 type, manufactured by Nikkiso Co., Ltd.).

In addition, the shape of the phosphorous-containing copper alloy particle is not particularly limited, and it may include any one of a spherical shape, a flat shape, a block shape, a plate shape, a scale-like shape and the like. From the standpoint of oxidation resistance and low resistivity, it is preferably a spherical shape, a flat shape, or a plate shape.

The content of the phosphorous-containing copper alloy particles, or the total content of the phosphorous-containing copper alloy particles and the silver particles when including silver particles as described later can be, for example, from 70% by mass to 94% by mass, and from the standpoint of oxidation resistance and low resistivity, preferably from 72% by mass to 90% by mass, and more preferably from 74% by mass to 88% by mass, based on the paste composition for an electrode according to the present invention.

The phosphorous-containing copper alloy used for the phosphorous-containing copper alloy particles can be prepared by a typically used method. The phosphorous-containing copper alloy particles can be prepared by a general method for preparing metal powders using a phosphorous-containing copper alloy that is prepared so as to give a desired phosphorous content with a general method, for example, a water atomization method. The water atomization method is described in Handbook of Metal (Maruzen) or the like.

Specifically, for example, a desired phosphorous-containing copper alloy particle can be prepared by dissolving a phosphorous-containing copper alloy, forming a power by a nozzle spray, drying the obtaining powders, and classifying them. A phosphorous-containing copper alloy particle having a desired particle diameter can be prepared by appropriately selecting the classification condition.

### (Glass Particles)

The paste composition for an electrode according to the present invention includes at least one glass particle. By including the glass particles in the paste composition for an electrode, the adhesion between the electrode portion and the substrate is improved. A silicon nitride film which is an anti-reflection film is removed by a so-called fire-through at an electrode forming temperature, and an ohmic contact between the electrode and the silicon substrate is formed.

As the glass particles, any known glass particles in the related art may be used without a particular limitation, provided the glass particles are softened or melted at an electrode-forming temperature to contact with the silicon nitride, thereby oxidizing the silicon nitride to be silicone oxide, incorporating the silicon dioxide thereof and then removing the anti-reflection film.

In the present invention, the glass particles preferably contain glass having a glass softening point of 600° C. or lower at a crystallization starting temperature of higher than 600° C., from the standpoint of the oxidation resistance and the low resistivity of the electrode. The glass softening point is measured by a general method using a ThermoMechancial Analyzer (TMA), and the crystallization starting temperature is measured by a general method using a ThermoGravimetry/Differential Thermal Analyzer (TG/DTA).

The glass particles generally included in the paste composition for an electrode may be constituted with lead-containing glass, at which silicon dioxide is efficiently captured. Examples of such lead-containing glass include those described in Japanese Patent 03050064 and the like, which can be preferably used in the present invention.

In the present invention, in consideration of an effect on the environment, it is preferable to use lead-free glass described in Paragraphs 0024 to 0025 of JP-A No. 2006-313744, and lead-free glass described in JP-A No. 2009-188281 and the like, and it is also preferable to appropriately select one from the lead-free glass as above for the present invention.

Examples of a glass component constituting a glass particle to be used in a paste composition for an electrode according to the present invention include silicon dioxide (SiO₂), phosphorous oxide (P₂O₅), aluminum oxide (Al₂O₃), boron oxide (B₂O₃), vanadium oxide (V₂O₅), potassium oxide (K₂O), bismuth oxide (Bi₂O₃), sodium oxide (Na₂O), lithium oxide (Li₂O), barium oxide (BaO), strontium oxide (SrO), calcium oxide (CaO), magnesium oxide (MgO), beryllium oxide (BeO), zinc oxide (ZnO), lead oxide (PbO), cadmium oxide (CdO), tin oxide (SnO), zirconium oxide (ZrO₂), tungsten oxide (WO₃), molybdenum oxide (MoO₃), lanthanum oxide (La₂O₃), niobrium oxide (Nb₂O₅), tantalum oxide (Ta₂O₅), yttrium oxide (Y₃O₃), titanium oxide (TiO₂), germanium oxide (GeO₂), tellurium oxide (TeO₂), lutetium oxide (Lu₂O₃), antimony oxide (Sb₂O₃), copper oxide (CuO), iron oxide (FeO), silver oxide (AgO) and manganese oxide (MnO).

Among these, it is preferred to use at least on selected from SiO₂, P₂O₅, Al₂O₃, B₂O₃, V₂O₅, Bi₂O₃, ZnO, or PbO. Specific examples of the glass component include one which contains SiO₂, PbO, B₂O₃, Bi₂O₃ and Al₂O₃. In the case of such glass particle, since the softening point is effectively lowered and the wettabilities with the phosphorous-containing copper alloy particle and the silver particle added as required are improved, sintering among the particles in the sintering process is advanced, so that an electrode having a low resistivity can be formed.

On another front, from the standpoint of attaining a low contact resistivity of a formed electrode, a glass particle containing diphosphorus pentoxide (phosphate glass, P₂O₅-based glass particle) is preferred and a glass particle which further contains divanadium pentoxide in addition to diphosphorous pentoxide (P₂O₅-V₂O₅-based glass particle) is more preferred. By further containing divanadium pentoxide, the oxidation resistance is more improved and the resistivity of the electrode is further reduced. This can be considered attributable to, for example, a decrease in the glass softening point attained by the further addition of divanadium pentoxide. In cases in which a diphosphorous pentoxide-divanadium pentoxide-based glass particle (P₂O₅-V₂O₅-based glass particle) is used, the content of divanadium pentoxide is preferably not less than 1% by mass, more preferably from 1% by mass to 70% by mass, based on the total mass of the glass.

The particle size of the glass particle is not particularly limited, and the particle size when the cumulative weight 50% (hereinafter abbreviated as “D50%” in some cases) is preferably from 0.5 μm to 10 μm, and more preferably from 0.8 μm to 8 μm. By controlling the particle size of the glass particle at not less than 0.5 μm, the workability at the time of the preparation of the electrode paste composition is improved. By controlling the particle size of the glass particle at not greater than 10 μm, it is easy that the glass particle is uniformly dispersed in the electrode paste composition, so that fire-through can occur efficiently in the calcination process, and the adhesion of the formed electrode with the silicon substrate is also improved.

The content of the glass particles is preferably from 0.1% by mass to 10% by mass more preferably from 0.5% by mass to 8% by mass, and still more preferably from 1% by mass to 7% by mass, based on the total mass of the paste composition for an electrode. By including the glass particles at a content in this range, oxidation resistance, low resistivity of the electrode and low contact resistance can be more effectively attained.

### (Solvent and Resin)

The paste composition for an electrode according to the present invention includes at least one solvent and at least one resin, thereby enabling adjustment of the liquid physical properties (for example, viscosity and surface tension) of the paste composition for an electrode according to the present invention due to the application method selected when the paste composition is provided on the silicon substrate.

The solvent is not particularly limited. Examples thereof include hydrocarbon solvents such as hexane, cyclohexane, and toluene; chlorinated hydrocarbon solvents such as dichloroethylene, dichloroethane and dichlorobenzene; cyclic ether solvents such as tetrahydrofuran, furan, tetrahydropyran, pyran, dioxane, 1,3-dioxolane and trioxane; amide solvents such as N,N-dimethylformamide and N,N-dimethylacetamide; sulfoxide solvents such as dimethylsulfoxide and diethylsulfoxide; ketone solvents such as acetone, methyl ethyl ketone, diethyl ketone and cyclohexanone; alcohol compounds such as ethanol, 2-propanol, 1-butanol and diacetaone alcohol; polyhydric alcohol ester solvents such as 2,2,4-trimethyl-1,3-pentanediol monoacetate, 2,2,4-trimethyl-1,3-pentanediol monopropiorate, 2,2,4-trimethyl-1,3-pentanediol monobutyrate, 2,2,4-trimethyl-1,3-pentanediol monoisobutyrate, 2,2,4-triethyl-1,3-pentanediol monoacetate, ethylene glycol monobutyl ether acetate and diethylene glycol monobutyl ether acetate; polyhydric alcohol ether solvents such as butyl cellosolve, diethylene glycol monobutyl ether and diethylene glycol diethyl ether; terpene solvents such as α-terpinene, α-terpineol, myrcene, alloocimene, limonene, dipentene, α-pinene, β-pinene, terpineol, carvone, ocimene and phellandrene; and mixtures thereof.

As the solvent in the present invention from the standpoint of applicability and printability when forming the paste composition for an electrode on a silicon substrate, at least one selected from polyhydric alcohol ester solvents, terpene solvents or polyhydric alcohol ester solvents is preferred, and at least one selected from polyhydric alcohol ester solvents or terpene solvents is more preferred.

In the present invention, the solvents may be used singly or in a combination of two or more kinds thereof.

As the resin, a resin that is usually used in the art can be used without any limitation as long as it is a resin that is thermally decomposable by sintering. Specific examples thereof include cellulose resins such as methyl cellulose, ethyl cellulose, carboxymethyl cellulose, and nitrocellulose; polyvinyl alcohols; polyvinyl pyrrolidones; acryl resins; vinyl acetate-acrylic ester copolymers, butyral resins such as polyvinyl butyral; alkyd resins such as phenol-modified alkyd resins and castor oil fatty acid-modified alkyd resins; epoxy resins; phenol resins; and rosin ester resins.

As the resin in the present invention, from the standpoint of the loss during sintering, at least one selected from cellulose resins or are preferred, and at least one selected from cellulose resins is more preferred.

In the present invention, the resins may be used singly or in combination of two or more kinds thereof.

The weight average molecular weight of the resin in the present invention is not particularly limited. In particular, the weight average molecular weight of the resin is preferably from 5,000 to 500,000, and more preferably from 10,000 to 300,000. When the weight average molecular weights of the resin is not less than 5,000, and increase in the viscosity of the paste composition for an electrode can be suppressed. This can be considered because, for example, mutual aggression of particles is suppressed, in which steric repulsion is exerted when the resin is adsorbed on the phosphorous-containing copper alloy particles. Meanwhile, when the weight average molecular weight of the resin is not higher than 500,000, mutual aggression of the resin in the solvent is suppressed, so that the phenomenon of increase in the viscosity of the paste composition for an electrode can be suppressed. In addition, by controlling the weight average molecular weight of the resin at an appropriate level, an increase in the combustion temperature of the resin can be inhibited and, therefore, a residual foreign substance caused by incomplete combustion of the resin during sintering of the paste composition for an electrode can be prevented, so that an electrode having a low resistivity can be attained.

In the paste composition for an electrode according to the present invention, the contents of the solvent and the resin can be appropriately selected in accordance with desired liquid physical properties and the kinds of the solvent and the resin to be used.

For example, the content of the resin is preferably from 0.01% by mass to 5% by mass, more preferably from 0.05% by mass and 4% by mass, still more preferably from 0.1% by mass to 3% by mass, and still more preferably from 0.15% by mass to 2.5% by mass, based on the total mass of the paste composition for an electrode.

The total content of the solvent and the resin is preferably from 3% by mass to 29.8% by mass, more preferably from 5% by mass to 25% by mass, and still more preferably from 7% by mass to 20% by mass, based on the total mass of the paste composition for an electrode.

By setting the contents of the solvent and the resin in the ranges, the provision suitability becomes better when the paste composition for an electrode is provided on a silicon substrate, and thus, an electrode having a desired width and a desired height can be formed more easily.

### (Silver Particle)

The paste composition for an electrode according to the present invention preferably further includes at least one silver particle. By including the silver particle, the oxidation resistance is further improved, and the resistivity as the electrode is further reduced. In addition, an effect that the solder connectivity is improved when forming a photovoltaic cell module can be obtained. This can be considered to be as follows, for example.

Generally, in a temperature region from 600° C. to 900° C. that is an electrode-forming temperature region, a solid solution of a small amount of silver into copper, and a solid solution of a small amount of copper into silver are generated, whereby a layer of the copper-silver solid solution (solid solution region) is formed at an interface between copper and silver. It is thought that when a mixture of the phosphorous-containing copper alloy particles and the silver particles is heated at a high temperature, and then slowly cooled to room temperature, the solid solution region is not generated, but taking into consideration that cooling is done for a few seconds from a high temperature region to a normal temperature when forming an electrode, it is thought that the layer of the solid solution at a high temperature covers the surface of the silver particles and the phosphorous-containing copper alloy particles as a non-equilibrium solid solution phase or as an eutectic structure of copper and silver. It can be thought that such the copper-silver solid solution layer contributes to the oxidation resistance of the phosphorous-containing copper alloy particle at an electrode-forming temperature.

The copper-silver solid solution layer starts to be formed at a temperature of 300° C. to 500° C. or higher. Therefore, it may be thought that, by using the silver particle in combination of a phosphorous-containing copper-containing particle whose peak temperature of the exothermic peak showing the maximum area in simultaneous differential thermal-thermogravimetric measurement is 280° C. or higher, the oxidation resistance of the phosphorus-and-copper-containing particle can be improved more effectively, so that the resistivity of the resulting electrode is further reduced.

The silver constituting the silver particle may contain other atom(s) that is/are unavoidably mixed therein. Examples such other atoms include Sb, Si, K, Na, Li, Ba, Sr, Ca, Mg, Be, Zn, Pb, Cd, Tl, V, Sn, Al, Zr, W, Mo, Ti, Co, Ni, and Au.

The content of such other atom(s) in the silver particle can be, for example, not higher than 3% by mass, and from the standpoints of the melting point and attaining an electrode having a low reactivity, it is preferably not higher than 1% by mass.

The particle diameter of silver particle in the present invention is not particularly limited, but it is preferably from 0.4 μm to 10 μm, and more preferably from 1 μm to 7 μm in terms of a particle diameter when the cumulative mass id 50% (“D50%”). By setting the particle diameter of the silver particle to 0.4 μm or more, the oxidation resistance is improved more effectively. By setting the particle diameter of the silver particle to 10 μm or less, the contact area between the metal particles such as silver particles and phosphorous-containing copper-containing alloy particles in the electrode increases; and thus, the resistivity of a formed electrode is more effectively reduced.

In the electrode paste composition according to the present invention, the relationship between the particle size (D50%) of the phosphorous-and-copper-containing particle and that of the silver particle is not particularly restricted; however, it is preferred that the particle size (D50%) of either one to that of the other is from 1 to 10. By this, the resistivity of the electrode is reduced more effectively. This may be thought to be attributed to, for example, an increase in the contact area among the metal particles, such as the phosphorous-and-copper-containing particle and the silver particle, in the electrode.

From the standpoints of the oxidation resistance and low resistivity of the electrode, the content of the silver particle in the electrode paste composition according to the present invention is preferably from 8.4% by mass to 85.5% by mass, and more preferably from 8.9% by mass to 80.1% by mass.

In the present invention, from the standpoints of the oxidation resistance and low resistivity of the electrode, taking the total amount of the phosphorous-and-copper-containing particle and the silver particle as 100% by mass, the content of the phosphorous-and-copper-containing particle is preferably from 9% by mass to 88% by mass, and more preferably from 17% by mass to 77% by mass. By controlling the content of the phosphorous-and-copper-containing particle and the silver particle, for example, when the glass particle contains divandium pentoxide, the reaction between silver and vanadium is suppressed, so that the volume resistance of the electrode is further reduced. In addition, in a treatment of a silicon substrate on which an electrode if formed with an aqueous hydrofluoric acid solution, which treatment is performed for the purpose of improving the energy conversion efficiency of a resulting photovoltaic cell, the resistance of the electrode material against the aqueous hydrofluoric acid solution (a property that the electrode material is not detached from the silicon substrate by the aqueous hydrofluric acid solution) is improved. Moreover, by controlling the content of the phosphorous-and-copper-containing particle at not higher the 88% by mass, the contact between copper contained therein and the silicon substrate is further inhibited, so that the contact resistance of the electrode is further reduced.

In the electrode paste composition according to the present invention, from the standpoints of the oxidation resistance, low resistivity of the electrode and coating property on the silicon substrate, the total content of the phosphorous-and-copper-containing particle and the silver particle is preferably from 70% by mass to 94% by mass, more preferably from 72% by mass to 92% by mass, still more preferably 72% by mass to 90% by mass, and still more preferably 74% by mass to 88% by mass.

By controlling the total content of the phosphorous-and-copper-containing particle and the silver particle are not less than 70% by mass, a viscosity suitable for providing the electrode paste composition can be easily attained. By controlling the total content of the phosphorous-and-copper-containing particle and the silver particle at not higher than 94% by mass, the occurrence of a phenomenon that the electrode paste composition is provided in a faint and patchy fashion can be inhibited more effectively.

In the electrode paste composition according to the present invention, from the standpoints of the oxidation and low resistivity of the electrode, it is preferred that the total content of the phosphorous-and-copper-containing particle and silver particle is from 70% by mass to 94% by mass, the content of the glass particle is from 0.1% by mass to 10% mass, and the total content of the solvent and the resin is from 3% by mass to 29.8% by mass; and it is more preferred than the total content of the phosphorous-and-copper-containing particle and the silver particle is from 74% by mass to 88% by mass, the content of the glass particle is from 1% by mass to 7% by mass, and the total content of the solvent and the resin is from 7% by mass to 20% by mass.

### (Phosphorus-Containing Compound)

The above-described electrode paste composition may further contain at least one phosphorus-containing compound. By this, the oxidation resistance is improved more effectively and the resistivity of the electrode is further reduced. In addition, the elements in the phosphorus-containing compound are diffused as n-type dopant in the silicon substrate, so that an effect that the power generation efficiency is improved when the electrode paste composition is used to prepare a photovoltaic cell can also be attained.

As the above-described phosphorus-containing compound, from the standpoints of the oxidation resistance and low resistivity of the electrode, a compound having a high content of phosphorus atom in the molecule, which does not undergo evaporation or decomposition at a temperature condition of about 200° C.

Specific examples of the above-described phosphorus-containing compound include phosphorus inorganic acids such as phosphoric acid; phosphates such as ammonium phosphate; phosphoric acid esters such as phosphoric acid alkyl esters and phosphoric acid aryl esters, cyclic phosphazenes such as hexaphenoxyphosphazene; and derivatives thereof.

The phosphorus-containing compound in the present invention is, from the standpoints of the oxidation resistance and low resistivity of the electrode, preferably at least one selected from the group consisting of phosphoric acid, ammonium phosphate, phosphoric acid esters and cyclic phosphazenes, and more preferably at least one selected from the group consisting of phosphoric acid esters and cyclic phosphazenes.

From the standpoints of the oxidation resistance and low resistivity of the electrode, the content of the above-described phosphorus-containing compound in the present invention is preferably from 0.5% by mass to 10% by mass, and more preferably from 1% by mass to 7% by mass, with respect to the total mass of the electrode paste composition.

In the present invention, the electrode paste composition contains, as the phosphorus-containing compound, preferably at least one selected from the group consisting of phosphoric acid, ammonium phosphate, phosphoric acid esters and cyclic phosphazenes in an amount of from 0.05% by mass to 10% by mass with respect to the total mass of the electrode paste composition; and more preferably at least one selected from the group consisting of phosphoric acid esters and cyclic phosphazenes in an amount of from 1% by mass to 7% by mass with respect to the total mass of the electrode paste composition.

### (Other Components)

The paste composition for an electrode according to the present invention may contain, in addition to the components described above, other components generally used in the art, if necessary. Examples of other components include a plasticizer, a dispersant, a surfactant, an inorganic binder, a metal oxide, a ceramic, and an organic metal compound.

The method of preparing the paste composition for an electrode according to the present invention is not particularly limited. The paste composition for an electrode according to the present invention can be prepared by dispersing and mixing the phosphorous-containing copper-containing particle, glass particles, a solvent, a resin, silver particles to be added, if necessary, and the like, using a typically used dispersing/mixing method.

In the present invention, it is preferred that a flux be coated on the electrode surface. The flux used for the electrode is the same as the one used in the later-described solder layer and their preferred ranges are also the same. In addition, the method of applying the flux on the electrode is also the same as the case in which the flux is applied on the solder layer.

### (Method for Preparing Electrode)

As a method of producing an electrode by using the paste composition for an electrode according to the present invention, an electrode can be formed in a desired region by providing the paste composition for an electrode to the region where an electrode is to be formed and then drying and sintering the resultant. By using the paste composition for an electrode, an electrode having a low resistivity can be formed even when the sintering treatment is performed in the presence of oxygen (e.g. in the atmosphere).

Specifically, for example, in cases in which an electrode for a photovoltaic cell is formed using the paste composition for an electrode, a photovoltaic cell electrode having a low resistivity can be formed in a desired shape by providing the paste composition for an electrode to a silicon substrate in a desired shape and the drying and sintering the resultant. By using the paste composition for an electrode, and electrode having a low resistivity can be formed even when the sintering treatment is performed in the presence of oxygen (e.g. in the atmosphere).

Examples of the method for providing the paste composition for an electrode on a silicon substrate include screen printing, and ink-jet method, and a dispenser method, and from the standpoint of the productivity, application by screen printing is preferred.

When the paste composition for an electrode according to the present invention is applied by screen printing, it is preferable that the viscosity be in the range from 80 Pa·s to 1000 Pa·s. The viscosity of the paste composition for an electrode is measured using a Brookfield HBT viscometer at 25° C.

The amount of the paste composition for an electrode to be applied can be selected as appropriate in accordance with the size of the electrode to be formed. For example, the paste composition for an electrode may be applied in an amount of from 2 g/m² to 10 g/m², and preferably from 4 g/m² to 8 g/m².

Moreover, as a heat treatment condition (sintering condition) when forming an electrode using the paste composition for an electrode according to the present invention, heat treatment conditions generally used in the art can be applied.

Generally, the heat treatment temperature (sintering temperature) is from 800° C. to 900° C., but when using the paste composition for an electrode according to the present invention, a heat treatment condition at a lower temperature can be applied, and for example, an electrode having excellent characteristics can be formed at a heat treatment temperature of from 600° C. to 850° C.

In addition, the heat treatment time can be appropriately selected according to the heat treatment temperatures, and it may be, for example, from 1 second to 20 seconds.

### <Solder Layer>

A solder layer according to the present invention is provided on the electrode, and connects the electrode and a tab wire or the like. The solder layer according to the present invention contains flux. By allowing the solder layer to contain a flux, the adhesion between the electrode and the solder layer is improved, and further an effect of reducing the contact resistance of the interface between the electrode and the solder layer is obtained.

The type of the soldering material which constitutes the solder layer is not particularly limited, and examples thereof include a lead-containing soldering material, and a lead-free soldering material. Specific examples of the lead-containing soldering material include Sn—Ph, Sn—Pb—Bi, and Sn—Pb—Ag. Examples of the lead-free soldering material include Sn—Ag—Cn, Sn—Ag, Sn—Sb, Sn—Cu, Bi—Sn, and In—Sn.

Among these, from the standpoint of environmental consciousness, a lead-free soldering material is preferably used. As the lead-free soldering material, a lead-free soldering material containing 32% by mass or higher of tin is more preferably used, and a lead-free soldering material containing 42% by mass or higher of tin is still more preferably used.

The flux according to the present invention is not particularly limited, as ling as it can remove a surface oxide film of an electrode and a solder layer and allow connection between the electrode and the solder layer by effects such as improvement of the wettability of the surface or inhibition of reformation of a surface oxide film. Specifically, for example, at least one flux component selected from an inorganic acid, a halide, an organic acid or rosin is preferably contained.

Examples of the inorganic acid include hydrogen bromide acid, hydrochloric acid, nitric acid, phosphoric acid, boric acid, sulfuric acid, and hydrofluoric acid. At least one selected from hydrogen bromide acid, hydrochloric acid, nitric acid, phosphoric acid or boric acid is preferably contained.

As the halide, at least one selected from chloride or bromide is preferably contained. Examples of the chloride include zinc chloride, ammonium chloride, methylene chloride, magnesium chloride, bismuth chloride, barium chloride, tin chloride, silver chloride, potassium chloride, indium chloride, antimony chloride, and aluminum chloride. At least one selected from zinc chloride or ammonium chloride is preferably contained. Examples of the bromide include phosphorus bromide, iodine bromide, methylene bromide, germanium bromide, sulfur bromide, ammonium bromide, and zinc bromide. At least one selected from ammonium bromide or zinc bromide is preferably contained.

Examples of the organic acid include a carboxylic acid compound, phenol derivatives, a sulfonic acid compound. A carboxylic acid compound is preferred from the viewpoint of easily removing a surface oxide film of an electrode and a solder layer. Examples of the carboxylic acid compound include formic acid, acetic acid, oxalic acid, lauric acid, myristic acid, palmitic acid, stearic acid, sorbic acid, stearolic acid, propionic acid, butyric acid, valeric acid, caproic acid, enanthic acid, caprylic acid, pelargonic acid, capric acid, margaric acid, oleic acid, linoleic acid, linolenic acid, arachidonic acid, docosahexaenoic acid, cicosapentaenoic acid, lactic acid, malic acid, citric acid, benzoic acid, phtalic acid, isophthalic acid, terephthalic acid, salicylic acid, gallic acid, mellatic acid, cinnamic acid, malonic acid, succinic acid, glutaric acid, adipic acid, fumaric acid, maleic acid, pyruvic acid, aconitic acid, amino acid, and nitro carboxylic acid. At least one selected from formic acid, acetic acid, or oxalic acid is preferably contained. Examples of the phenol derivatives include a phenol resin, salicylic acid, picric acid. A phenol resin is preferably contained.

In the present invention, these flux components may be used singly or in combination of two or more kinds thereof. When two or more kinds thereof are used in combination, suitable examples thereof include a combination of rosin and an organic acid, a combination of rosin and an inorganic acid, a combination of rosin and a halide, a combination of an inorganic acid an a halide, and a combination of a halide and a halide. More suitable examples thereof include a combination of rosin and an organic acid, a combination of rosin and an inorganic acid, and a combination of rosin and a halide. In cases in which rosin and other flux components are combined, rosin is contained preferably in an amount of from 5% by mass to 40% by mass, more preferably in an amount of from 10% by mass to 30% by mass, and still more preferably in an amount of from 12% by mass to 20% by mass with respect to the total flux component.

From the standpoint of workability during application on an electrode and a solder layer, the flux may contain a solvent. The solvent is appropriately selected depending on types of the flux components such as an inorganic acid, halide, an organic acid, and rosin.

Examples of the solvent include water; ether acetate solvents such as ethylene glycol methyl ether propionate, ethylene glycol ethyl ether propionate, butyl carbitol acetate, ethylene glycol methyl ether acetate, ethylene glycol ethyl ether acetate, diethylene glycol methyl ether acetate, diethyl glycol ethyl ether acetate, diethylene glycol-n-butyl ether acetate, propylene terpene solvents such as α-terpinene, α-terpineol, myrcene, allo-ocimene, limonene, dipentene, α-pinene, β-pinene, terpineol, carvone, ocimene, and phellandrene, alcohol solvents such as methanol, ethanol, n-propanol, i-propanol, n-butanol, i-butanol, sec-butanol, t-butanol, n-petanol, i-pentanol, 2-methyl butanol, sec-pentanol, t-pentanol, 3-methoxy butanol, n-hexanol, 2-methyl pentanol, sec-hexanol, 2-ethyl butanol, sec-heptanol, n-octanol, 2-ethyl hexanol, sec-octanol, n-nonyl alcohol, n-decanol, sec-undecyl alcohol, trimethyl nonyl alcohol, sec-tetradecyl alocohol, sec-heptadecyl alcohol, phenol, cyclohexanol, methyl cyclohexanol, benzyl alcohol, ethylene glycol, 1,2-propylene glycol, 1,3-butylene glycol, diethylene glycol, dipropylene glycol, glycerin, triethylene glycol, and tripropylene glycol; ketone solvents such as acetone, methyl ethyl ketone, methyl-n-propyl ketone, methyl-iso-propyl keytone, methyl-n-butyl ketone, methyl-iso-butyl ketone, trimethyl nonanone, cyclohexanone, cyclopentanone, methyl cyclohexanone, 2,4-pentane dione, acetonylacetone, γ-butyrolactone, and γ-valerolactone; ether solvent such as diethyl ether, methyl ethyl ether, methyl-n-propyl ether, di-iso-propyl ether, tetrahydrofuran, methyl tetrahydrofuran, dioxane, dimethyl dioxane, ethylene glycol dimethyl ether, ethylene glycol diethyl ether, ethylene glycol di-n-propyl ether, ethylene glycol dibutyl ether, diethylene glycol dimethyl ether, diethylene glycol diethyl ether, diethylene glycol methyl ethyl ether, diethylene glycol methyl mono-n-propyl ether, diethylene glycol methyl mono-n-butyl ether, diethylene glycol di-n-propyl ether, diethylene glycol di-n-butyl ether, diethylene glycol methyl mono-n-hexyl ether, triethylene glycol dimethyl ether, triethylene glycol diethyl ether, triethylene glycol methyl ethyl ether, triethylene glycol methyl mono-n-butyl ether, triethylene glycol di-n-butyl ether, triethylene glycol methyl mono-n-hexyl ether, tetraethylene glycol dimethyl ether, tetraethylene glycol diethyl ether, tetradiethylene glycol methyl ethyl ether, tetraethylene glycol methyl mono-n-butyl ether, diethylene glycol di-n-butyl ether, tetraethylene glycol methyl mono-n-hexyl ether, tetraethylene glycol di-n-butyl ether, propylene glycol dimethyl ether, propylene glycol diethyl ether, propylene glycol di-n-propyl ether, propylene glycol dibutyl ether, dipropylene glycol dimethyl ether, dipropylene glycol diethyl ether, dipropylene glycol methyl ethyl ether, dipropylene glycol methyl mono-n-butyl ether, dipropylene glycol di-n-propyl ether, dipropylene glycol di-n-butyl ether, dipropylene glycol methyl mono-n-hexyl ether, tripropylene glycol dimethyl ether, tripropylene glycol diethyl ether, tripropylene glycol methyl ethyl ether, tripropylene glycol methyl mono-n-butyl ether, tripropylene glycol di-n-butyl ether, tripropylene glycol methyl mono-n-hexyl ether, tetrapropylene glycol dimethyl ether, tetrapropylene glycol diethyl ether, tetradipropylene glycol methyl ethyl ether, tetraproprylene glycol methyl mono-n-butyl ether, dipropylene glycol di-n-butyl ether, tetrapropylene glycol methyl mono-n-hexyl ether, and tetraproprylene glycol di-n-butyl ether, ester solvents such as methyl acetate, ethyl acetate, n-propyl acetate, i-propyl acetate, n butyl acetate, i-butyl acetate, sec butyl acetate, n-pentyl acetate, sec-pentyl acetate, 3-methoxy butyl acetate, methyl pentyl acetate, 2-ethyl butyl acetate, 2-ethyl hexyl acetate, 2-(2-butoxy ethoxy) ethyl acetate, benzyl acetate, cyclohexyl acetate, methyl cyclohexyl acetate, nonyl acetate, methyl acetoacetate, ethyl acetoacetate, diethylene glycol monomethyl ether acetate, dimetyl glycol mono ethyl ether acetate, diethylene glycol mono-n-butyl ether acetate, dipropylene glycol monomethyl ether acetate, dipropylene glycol mono ethyl ether acetate, glycol diacetate, methoxy triglycol acetate, ethyl propionate, n-butyl propionate, i-amyl propionate, diethyl oxalate, di-n-butyl oxalate, methyl lactate, ethyl lactate, n-butyl lactate, and n-amyl lactate; aprotonic polar solvents such as acetonitrile, N-methyl pyrrolidinone, N-ethyl pyrrolidinone, N-propyl pyrrolidinone, N-butyl pyrrolidinone, N-hexyl pyrrolidinone, N-cyclohexyl pyrrolidinone, N,N-dimethylformamide, N,N-dimethylacetamide, and dimethyl sulphoxide; and glycol monoether solvents such as ethylene glycol methyl ether, ethylene glycol ethyl ether, ethylene glycol monophentyl ether, diethylene glycol monomethyl ether, diethylene glycol mono ethyl ether, diethylene glycol mono-n-butyl ether, diethylene glycol mono-n-hexyl ether, ethoxy triglycol, tetraethylene glycol mono-n-butyl ether, propylene glycol monomethyl ether, dipropylene glycol monomethyl ether, dipropylene glycol mono ethyl ether, and tripropylene glycol monomethyl ether. These may be used singly or in combination of two or more kinds thereof.

In cases which rosin is used as a flux component in the flux, glycerin, ethylene glycol, isopropanol or the like is preferably used for a solvent. In cases in which the inorganic acid is used as a flux component, water, butyl carbitol acetate or the like is preferably used for a solvent. In cases in which the halide is used as a flux component, water, terpineol, or the like is preferably used. In cases in which an organic acid is used as a flux component, glycerin, ethylene glycol, isopropanol or the like is preferably used.

The flux may contain other components. Examples of other components include an ester of the carboxylic acid compound mentioned above. Specific exampled of the ester of the carboxylic acid compound include ethyl acetate, trimethyl borate, methyl butyrate, methyl salicylate, ethyl formate, ethyl butyrate, ethyl caproate, pentyl acetate, isopentyl acetate, pencyl valerate, pentyl butyrate, and octyl acetate. At least one selected from ethyl acetate or trimethyl borate is preferably contained.

It is preferred that the content of a flux component in the flux is appropriately adjusted. For example, in cases in which the flux component is rosin, rosin is preferably contained in the flux in an amount of 5% by mass or higher, from the viewpoint that a surface oxide film of an electrode and a solder layer can be easily removed; and still more preferably in an amount of 10% by mass or higher. The upper limit value is not particularly limited, and preferably, rosin is contained in an amount of 40% by mass or less, and more preferably in an amount of 30% by mass or less, from the standpoint of applicability.

In cases where the flux component is an inorganic acid, a halide or an organic acid, the flux component in the flux is preferably contained in an amount of from 1% by mass to 15% by mass, from the viewpoint that a surface oxide film of an electrode and a solder layer can be easily removed; and more preferably contained in an amount of from 2% by mass to 10% by mass.

A method of including the flux in solder layer is not particularly limited. From the viewpoint of improving the adhesion between the electrode and the solder layer, it is preferable that a flux exists at least on the surface of the solder layer. Examples of a method of producing such a solder layer include a method in which a flux is applied on the least one surface of the electrode or the solder layer.

A method of including a flux in the solder layer is not particularly limited, and examples thereof include a method in which a flux is applied on at least one surface of the electrode and the solder layer. When a flux is applied, a liquid containing the flux component and the solvent may be applied. Alternatively, a solvent may be applied. In cases in which the electrode has an absorbency, it is also suitable that a liquid containing a flux component and a solvent is applied after application of a solvent, from the viewpoint that an oxide film of an electrode surface can be effectively removed without soaking of the flux component into the electrode.

Even in cases in which a flux is applied on an electrode surface and not applied on the surface of a solder layer, the solder layer contains a flux by allowing the electrode and the solder layer to be in contact with each other and heat-treating them. When the application amount a flux to be applied on the surface of the electrode is less, it is preferable that the flux is also applied on the surface of the solder layer.

The method of applying a flux and the amount of the application are not particularly limited, and application by manual operation using an absorbent cotton or the like, or an automatic application by an application device attached to a bonding machine as described below or the like may be applied.

The electrode and the solder layer prepared as described above are allowed to be in contact and press with each other, and further, they are heat-treated, whereby the electrode and the solder layer are connected with each other.

In general, a pressing pressure during heat-treating an electrode and a solder which connects the electrode is about 2 MPa. In the present invention, sue to the improvement of wettability between an electrode and a solder layer, the pressing pressure may be set to 1.5 MPa or lower. By reducing the pressing pressure during heat-treatment of an electrode and a solder layer, decrease in a yield rate due to breaking off a silicon substrate during pressing can be prevented.

The heat treatment temperature during the connection may be appropriately selected depending on flux and a soldering material, and the temperature of the electrode and solder layer may be set, for example, to 125° C. to 350° C.

The pressing time may be appropriately selected depending on the types of flux and soldering material, and the heat treatment temperature, and may be set, for example, to from 2 seconds to 120 seconds.

As a heat treatment methods, a heat treatment by manual operation using a hotplate, heat blowing, soldering iron, an oven or the like, or an automatic heat treatment machine utilizing a machine such as a pulse heat bonding machine, a heat pressing machine, or an ultrasonic bonding machine.

As a post-treatment of the heat-treatment of an electrode and a solder which connects the electrode, cleaning for removing a flux may be performed. In particular, in cases in which a flux which contains a large amount of halide and by residue of which corrosion may proceed is used, the flux is desirably removed elaborately by using an ultrasonic cleaning or the like.

### <Use>

The use of the element according to the present invention is not particularly restricted and it may be used as a photovoltaic cell element, electroluminescence element and the like.

### <Photovoltaic Cell Element>

In the photovoltaic cell element according to the present invention, the substrate in the element has an impurity diffusion layer on which the electrode is formed and a solder layer containing a flux is formed on the electrode. By this, a photovoltaic cell element having excellent characteristics can be obtained and excellent productivity of the photovoltaic cell can be attained.

Here, the term “photovoltaic cell element” used herein refers to one which has a silicon substrate on which a pn junction is formed and an electrode formed on the silicon substrate. The term “photovoltaic cell” used herein refers to one which is constituted by providing a tab wore on the electrode of the photovoltaic cell element, and connecting, as required, plural photovoltaic cell elements via the tab wire.

Hereinbelow, specific examples of the photovoltaic cell of the present invention will be described with reference to the drawings, but the present invention is not limited thereto.

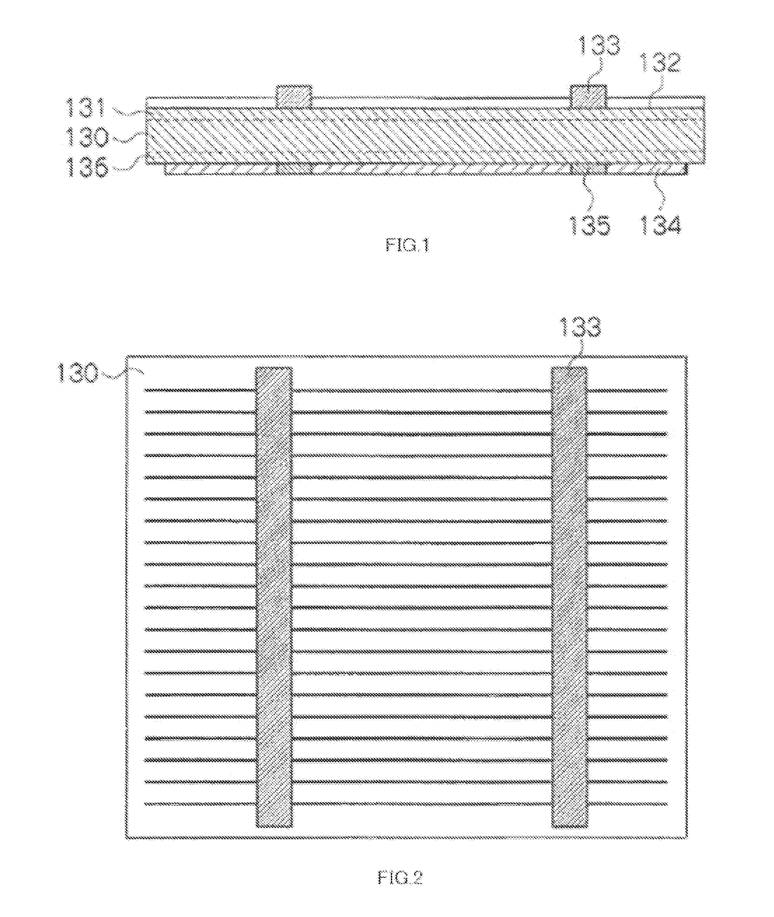

A cross-sectional view, and schematic diagrams of the light-receiving surface and the back surface of one example of the representative photovoltaic cell elements are shown in FIGS. 1, 2, and 3, respectively.

Typically, monocrystalline or polycrystalline Si, or the like is used as a semiconductor substrate 130 of a photovoltaic cell element. The semiconductor substrate 130 contains boron and the like, and constitutes a p-type semiconductor. Unevenness (texture, not shown) is formed on the light-receiving surface side by etching so as to inhibit the reflection of sunlight. As illustrated in FIG. 1, a phosphorous and the like are doped on the light-receiving surface side, a diffusion later 131 of an n-type semiconductor with a thickness on the order of submicrons is provided, and a p/n junction is formed on the boundary with the p-type bulk portion. Also, on the light-receiving surface side, and anti-reflective layer 132 such as silicon nitride with a film thickness of around 100 nm is provided on the diffusion layer 131 by a vapor deposition method.

Next, a light-receiving surface electrode 133 provided on the light-receiving surface side, a current collection electrode 134 and an output extraction electrode 135 formed on the back surface will be described. The light-receiving surface electrode 133 and the output extraction electrode 135 are formed from the paste composition for an electrode. The current collection electrode 134 is formed from the aluminum electrode paste composition including glass powders. These electrodes are formed by applying the paste composition for a desired pattern by screen printing or the like, drying, and then sintering at about 600° C. to 850° C. in an atmosphere.

Here, on the light-receiving surface side, the glass particles which are included in the paste composition for an electrode forming the light-receiving surface electrode 113 undergo a reaction (fire-through) with the anti reflection layer 132, thereby electrically connecting (ohmic contact) the light-receiving surface electrode 113 and the diffusion layer 131.

In the present invention, by using the paste compostion mentioned above for an electrode to form the light-receiving surface electrode 133, the light-receiving surface electrode 133 which includes copper as a conductive metal, inhibits the oxidation of copper, and has a low resistivity is formed with high productivity.

When a solder layer (not illustrated) containing a flux is provided on the outer surface of the light-receiving surface electrode 133, the adhesion between the light-receiving surface electrode 133 and the solder layer improves, and further, the contact resistance of the interface between the light-receiving surface electrode 133 and the solder layer is reduced.

On the back surface side, while sintering, aluminum in the aluminum electrode paste compostion forming the current collection electrode 134 is diffused onto the back surface of the semiconductor sunstrate 130 to form an electrode component diffusion layer 136, and as a result, ohmic contact among the semiconductor substrate 130, the current collection electrode 134, and the output extraction electrode 135 can be obtained.

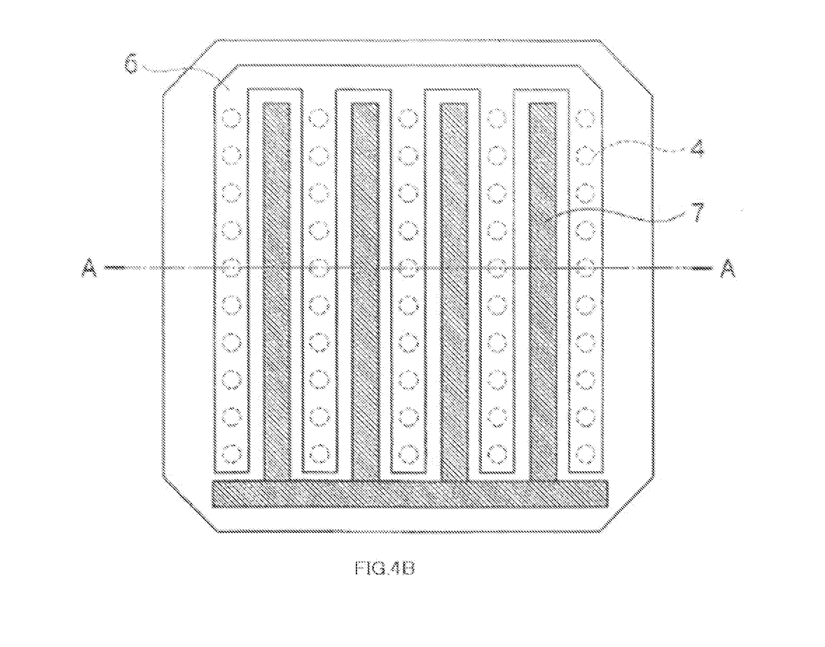

FIG. 4 is one example of a back contact-type photovoltaic cell element, which is another embodiment of the photovoltaic cell element according to the present invention. FIG. 4A is a perspective view showing the light-receiving surface and the structure of the A-A cross-section and FIG. 4B is a plan view showing the structure of the back surface electrode.

As illustrated in FIG. 4A, in cell wafer 1 including a silicon substrate of a p-type semiconductor, a through-hole which passes through both sides of the light-receiving surface side and the back surface side is formed by laser drilling, etching, or the like. A texture (not shown) improving the efficiency of incident light is formed on the light-receiving surface side. Also, the n-type semiconductor layer 3 by n-type diffusion treatment is formed on the light-receiving surface side, and the anti-reflective film (not shown) is formed on the n-type semiconductor layer 3. These are prepared by the same process as for a conventionally crystal Si-type photovoltaic cell element.

Next, the paste composition for an electrode according to the present invention is filled in the inside of the through-hole previously formed by printing method or an ink-jet method, and also, the paste composition for an electrode according to the present invention is similarly printed in the grid shape on the light-receiving surface side, thereby forming a composition layer which forms the through-hole electrode 4 and the grid electrode 2 for current collection.

Here, in the paste used for filling and printing, a paste having a composition optimal for each process including viscosity is preferably used, but a paste have the same composition may be filled or printed as a package.

On the other hand, a high-concentration doped layer 5 is formed on the back side of the light-receiving surface (back surface side) so as to prevent the carrier recombination. Here, as an impurity element forming the high-concentration doped layer 5, boron (B) or aluminum (Al) is used to form a p⁺ layer. This high concentration doped layer 5 may be formed by carrying out a thermal diffusion treatment using, for example, B as a diffusion source in the process of preparing an element before forming the anti-reflection film, or when using Al, it may also be formed by printing an Al paste on the back surface side in the printing process.

Thereafter, the paste composition for an electrode which is sintered at 650 to 850° C., and filled and printed on an anti-reflection film formed in the inside of the through-hole and on the light-receiving surface side can attain ohmic contact with the lower n-type layer by a fire-through effect.

As illustrated in the plan view of FIG. 4B, the paste composition for an electrode according to the present invention is printed in stripe shapes on each of the n side and the p side, and sintered, and thus, the back surface electrodes 6 and 7 are formed on the back surface side.

In the present invention, by using the electrode paste composition to form on the back surface electrode 6 and back surface electrode 7, the back surface electrode 6 and back surface electrode 7, which contain copper as a conductive metal while oxidation thereof is inhibited and which have a low resistivity, are formed with excellent productivity. When a solder layer (not illustrated) containing a flux is provided on the outer surface of the back surface electrode 6 and back surface electrode 7, the adhesion between the back surface electrode 6 and back surface electrode 7 and the solder layer improves, and further, the contact resistance of the interface between the back surface electrode 6 and back surface electrode 7 and the solder layer is reduced.

Moreover, the paste composition for an electrode for a photovoltaic cell of the present invention is not restricted to applications of photovoltaic cell electrodes, and can also be appropriately used in applications such as, for example, electrode wiring and shield warnings of plasma displays, ceramic condensers, antenna circuits, various sensors circuits, and heat dissipation materials of semiconductor devices.

### <Photovoltaic Cell>

The photovoltaic cell according to the present invention contains at least one photovoltaic cell element described in the above and is constituted in such a manner that a tab wire is arranged on the electrode of the photovoltaic cell element. Since the electrode surface is provided with a solder layer containing a flux, the adhesion between the electrode and the solder layer improves, and further, the contact resistance of the interface between the electrode and the solder layer is reduced, thereby obtaining a photovoltaic cell having an excellent battery performance.

The photovoltaic cell may also be connected, as required, with plural photovoltaic cell elements via the tab wire and may be constituted to be sealed with a sealing material as well. The tab wire and sealing material are not particularly restricted and they may be selected as appropriate from those which are normally employed in the art.

Examples of embodiments contained in the present invention is described below.

(1) An element including:
a silicon substrate;
an electrode that is provided on the silicon substrate and that is a sintered product of a paste composition for an electrode, the paste composition containing a phosphorous-containing copper alloy particle, a glass particle, a solvent, and a resin; and
a solder layer containing a flux, the solder layer being provided on the electrode.

(2) The element according to the item (1), in which the flux contains at least one selected from a halide, an inorganic acid, an organic acid or rosin.

(3) The element according to the item (2), in which the halide is at least one selected from chloride or bromide.

(4) The element according to the item (2), in which the inorganic acid contains at least one selected from hydrochloric acid, hydrogen bromide acid, nitric acid, phosphoric acid or boric acid.

(5) The element according to the item (2), in which the organic acid contains carboxylic acid.

(6) The element according to the item (5), in which the carboxylic acid contains at least one selected from formic acid, acetic acid or oxalic acid.

(7) The element according to any one of the items (2) to (6), in which the flux contains a rosin at 5% by mass or higher.

(8) The element according to any one of the items (1) to (7), in winch the solder layer contains a tin at 42% by mass or higher.

(9) The element according to any one of the items (1) to (8), in which the flux is contained in a combination of rosin and an organic acid, a combination of rosin and an inorganic acid, a combination of rosin and a halide, a combination of inorganic acid and a halide or a combination of a halide and a halide.

(10) The element according to any one of the items (1) to (8), in which the flux contains rosin and at least one selected from glycerin, ethylene glycol or isopropanol.

(11) The element according to any one of the items (1) to (8), in which the flux contains inorganic acid and at least one selected from water or butyl carbitol acetate.

(12) The element according to any one of the items (1) to (8), in which the flux contains halide and at least one selected from water or terpineol.

(13) The element according to any one of the items (1) to (8), in which the flux contains an organic acid and at least one selected from glycerin, ethylene glycol or isopropanol.

(14) The element according to any one of the items (2) to (13), in which the flux further contains a carboxylic acid ester.

(15) The element according to the item (14), in which the carboxylic acid ester is at least one selected from ethyl acetate, trimethyl borate, methyl butyrate, methyl salicylate, ethyl formate, ethyl butyrate, ethyl caproate, ethyl acetate, isopentyl acetate, pencyl valerate, pentyl butyrate, or octyl acetate.

(16) The element according to any one of the items (1) to (15), in which the content of phosphorous contained in the phosphorus-containing copper alloy particles is from 6% by mass to 8% by mass.

(17) The element according to any one of the items (1) to (16), in which the weight-average molecular weight of the resin is from 5,000 to 500,000.

(18) The element according to any one of the items (1) to (17), in which the paste composition for an electrode further contains a silver particle.

(19) The element according to the item (18), in which the content of the silver particle in the paste composition for an electrode is from 8.4% by mass to 85.5% by mass.

(20) The element according to the item (18) or (19), in which the relationship between the particle size (D50%) of the phosphorous-containing copper-containing particle and the particle size (D50%) of the silver particle satisfies a requirement that the ratio of the other particle size to one particle size is from 1 to 10.

(21) The element according to any one of the items (18) to (20), in which the content of a phosphorous-containing copper-containing particle is from 9% by mass to 88% by mass when setting the total amount of the phosphorous-containing copper-containing particle and the silver particle to 100% by mass.

(22) The element for a photovoltaic cell comprising the element according to any one of the items (1) to (21), in which the silicon substrate includes an impurity diffusion layer to be pn-joined, and the electrode is provided on the impurity diffusion layer.

(23) A photovoltaic cell including
the element for a photovoltaic cell according to the item (22), and
a tab wire connected to a solder layer of an electrode of the element.

The method of producing the element according to any one of the items (1) to (23), including:
a process of applying the flux on at least one surface of the electrode and the solder layer; and
a process of allowing the electrode and the solder layer to be in contact with each other at a surface on which the flux has been applied and heat-treating the resultant.

(25) The method of producing the element according to the item (24), in which the pressing pressure during allowing the electrode and the solder layer to be in contact with each other and heat-treating the resultant is 1.5 MPa or lower.

(26) The method of producing the element according to the item (24) or (25), in which a solvent is applied before the flux is applied.

(27) A flux provided between an electrode that is a sintered product of a paste composition for an electrode containing a phosphorus-containing copper alloy particle, a glass particle, a solvent and a resin, and a solder layer, containing:
at least one flux component selected from a halide, an inorganic acid, an organic acid or rosin; and
at least one solvent selected from water, an ether acetate solvent, a terpene solvent, an alcohol solvent, a ketone solvent, an ether solvent, an ester solvent, an aprotonic polar solvent or a glycol monoether solvent.

(28) The flux according to the item (27), in which the flux component in contained in a combination of rosin and an organic acid, a combination of rosin and an inorganic acid, a combination of rosin and a halide, a combination of an inorganic and a halide or a combination of a halide and a halide.

(29) The flux according to the item (27) or (28), in which the flux component contains rosin, and the solvent contains at least one selected from glycerin, ethylene glycol or isopropanol.

(30) The flux according to the item (27) or (28), in which the flux component contains an inorganic acid, and the solvent contains at least one selected from water or butyl carbitol acetate.

(31) The element according to the item (27) or (28), in which the flux component contains a halide, and the solvent contains at least one selected from water or terpineol.

(32) The element according to the item (27) or (28), in which the flux component contains an organic acid, and the solvent contains at least one selected from glycerin, ethylene glycol or isopropanol.

(33) The flux according to any one of the items (27) to (32), further containing a carboxylic acid ester.

(34) The flux according to item (33), in which the carboxylic acid ester is at least one selected from ethyl acetate, trimethyl borate, methyl butyrate, methyl salicylate, ethyl formate, ethyl butyrate, caproic acid ethyl, pentyl acetate, isopentyl acetate, pencyl valerate, pentyl butyrate or ocryl acetate.

The disclosure of Japanese Patent Application No. 2011-162598 is incorporated herein in by reference its entirety.

All literatures, patent applications, and technical standards described herein are herein incorporated by reference to the same extent as if each individual literature, patent application, or technical standard was specifically and individually indicated as being incorporated by reference.

### EXAMPLES

Hereinbelow, the present invention will be described in detail with reference to Examples, but the present invention is not limited to these Examples. Unless otherwise specified, “parts” and “%” are based on mass.

### Example 1

### (a) Preparation of Paste Composition for Electrode

A phosphorous-containing copper alloy particle including 7% by mass of phosphorous was prepared in accordance with a standard method, dissolved, made into powder by a water atomization method, then dried and classified. The classified powders were blended and subjected to deoxidation/dehydration treatments to adjust the phosphorous-containing copper alloy particles includeing 7% by mass of phosphorous (hereinafter abbreviated as “Cu7P” in some cases). The particle diameter of the phosphorous-containing copper alloy particle (D50%) was 5 μm.

A glass including 3 parts of silicon dioxide (SiO₂), 60 parts of lead oxide (PbO), 18 parts of boron oxide (B₂O₃), 5 parts of bismuth oxide (Bi₂O₃), 5 part of aluminum oxide (Al₂O₃), and 9 parts of zinc oxide (ZnO) (hereinafter abbreviated as “G1” in some cases) was prepared. The glass G1 obtained had a softening point of 420° C. and a crystallization temperature of 600° C. or higher.

By using the glass G1 obtained, glass particles having a particle diameter (D50%) of 1.1 μm were obtained.

Then, 85.1 parts of the thus obtained phosphorous-containing copper alloy particle Cu7P, 1.7 parts of the glass particle G1 and 13.2 parts of a terpineol (isomeric mixture) solution containing 3% by mass of ethyl cellulose (EC, weight average molecular weight of 190,000) were mixed and stirred in an agate mortar for 20 minutes to prepare a paste compostion for an electrode Cu7PG1.

### (b) Preparation of Photovoltaic Cell Element

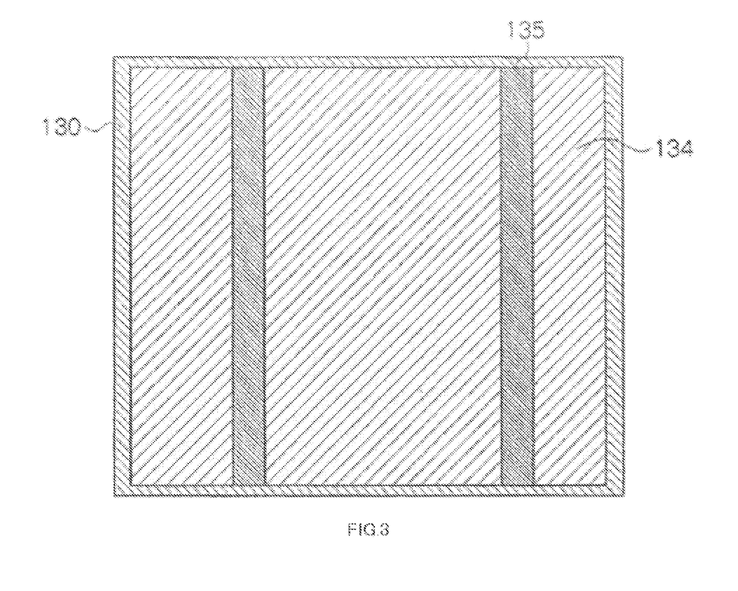

A p-type semiconductor substrate having a film thickness of 190 μm, in which an n-type semiconductor layer, a texture and an anti-reflection film (silicon nitride film) were formed on the light-receiving surface, was prepared, and cut to a size of 125 mm×125 mm. A silver paste composition for an electrode (manufactured by E.I. duPont de Nemours & Company, conductive paste SOLAMET159A) was printed on the light-receiving surface for an electrode pattern as illustrated in FIG. 2, using a screen printing method. The pattern of the electrode was composed of finger lines having a 150 μm width and bus bars having a 1.1 mm width, and the printing conditions (a mesh of a screen plate, a printing speed, a printing pressure) were appropriately adjusted so as to give a film thickness after sintering of about 5 μm. The resultant was put into an oven heated at 150° C. for 15 minutes, and the solvent was removed by evaporation.

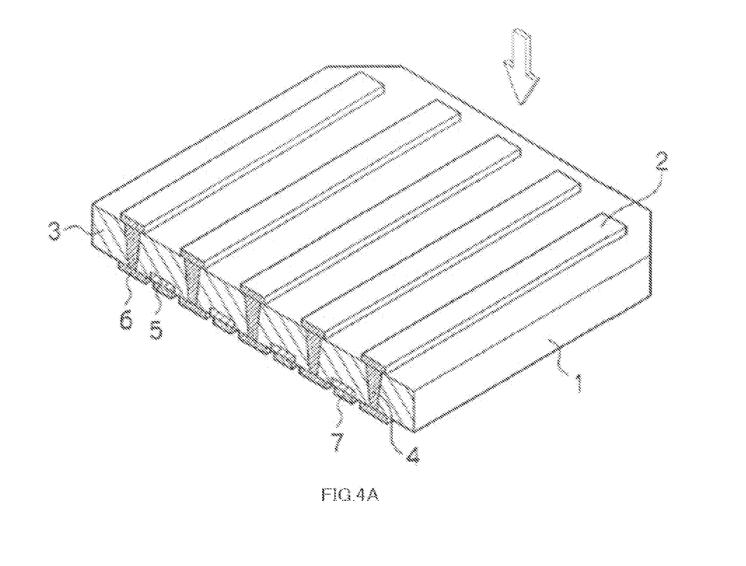

Subsequently, an aluminum electrode paste (manufactured by PVG Solutions Inc., SOLAR CELL PASTE (A1) HYPERBSF A1 PASTE) was similarly printed on the whole back surface thereof except for a portion where a power output electrode is formed as illustrated in FIG. 3. Printing conditions were appropriately adjusted such that the film thickness after sintering was 40 μm. The resultant was placed in an oven heated at 150° C. for 15 minutes, and a solvent was removed by evaporation.

Further, heat-treatment (sintering) was performed in an infrared rapid heating furnace for two seconds at 850° C. in the atmosphere to obtain a light-receiving surface electrode and a current collecting electrode.

Next, the paste composition Cu7PG1 for an electrode obtained above was printed on the back surface thereof so that an electrode pattern as illustrated in a pattern of a power output electrode in FIG. 3 was formed. The pattern of the electrode was constituted by bus bars having a width of 4 mm, and printing conditions (screen printing plate mesh, printing speed, printing pressure) were appropriately adjusted so that the film thickness after sintering was 15 μm. The resultant was placed in an oven heated at 150° C. for 1.5 minutes, and a solvent was removed by evaporation.

Subsequently, heat-treatment (sintering) was performed in an infrared rapid heating furnace for 10 seconds at 600° C. in the atmosphere to obtain a power output electrode.

Next, as a flux, an aqueous hydrochloric acid solution (hydrochloric acid concentration 2%) containing zinc chloride and 5% ammonium chloride was applied on the power output electrode obtained above in an appropriate amount using a brush. A copper wire, (usually, called “tab wire”) coated with solder Sn96.5Ag3Cu0.5 (hereinafter, solder is indicated by using a sign in accordance with JISZ3282) was placed thereon. Although a flux was not particularly applied on a solder, when the solder was placed on a power output electrode, the solder was wet with a flux.

Subsequently, the semiconductor substrate on which the solder coated tab wire described above was placed was placed on a hotplate to be heated to 250° C. while applying a pressing load on the tab wire. The pressing load on the tab wire was adjusted to about 1.0 MPa in unit area equivalent.

The resultant was then cooled to produce a photovoltaic cell element 1 on which an electrode which was connected with a desired solder was formed.

### Example 2

A photovoltaic cell element 2 on which an electrode which was connected with a desired solder was produced in a similar manner to Example 1 except that the flux was changed from an aqueous hydrochloric acid solution containing 5% zinc chloride and 5% ammonium chloride to butyl carbitol acetate (hereinafter abbreviated as “BCA” in some cases) containing 10% hydrogen bromide acid.

### Example 3

A photovoltaic cell element 3 on which an electrode which was connected with a desired solder was produced in a similar manner to Example 1 except that the flux was changed from an aqueous hydrochloric acid solution containing 5% zinc chloride and 5% ammonium chloride to an aqueous solution containing 5% hydrochloric acid.

### Example 4

A photovoltaic cell element 3 on which an electrode which was connected with a desired solder was produced in a similar manner to Example 1 except that the flux was changed from an aqueous hydrochloric acid solution containing 5% zinc chloride and 5% ammonium chloride to an aqueous solution containing 5% zinc chloride and 5% hydrochloric acid.

### Example 5

A photovoltaic cell element 5 on which an electrode which was connected with a desired solder was produced in a similar manner to Example 1 except that the flux was changed from an aqueous hydrochloric acid solution containing 5% zinc chloride and 5% ammonium chloride to terpineol containing 5% zinc chloride and 2% ammonium chloride.

### Example 6

A photovoltaic cell element 6 on which an electrode which was connected with a desired solder was produced in a similar manner to Example 1 except that the flax was changed from an aqueous hydrochloric acid solution containing 5% zinc chloride and 5% ammonium chloride to isopropanol (hereinafter abbreviated as “IPA” in some cases) containing 3% oxalic acid and 6% phenol resin.

### Example 7

A photovoltaic cell element 7 on which an electrode which was connected with a desired solder was produced in a similar manner to Example 1 except that the flax was changed from an aqueous hydrochloric acid solution containing 5% zinc chloride and 5% ammonium chloride to glycerin containing 2% acetic acid.

### Example 8

A photovoltaic cell element 8 on which an electrode which was connected with a desired solder was produced in a similar manner to Example 1 except that the flax was changed from an aqueous hydrochloric acid solution containing 5% zinc chloride and 5% ammonium chloride to IPA containing 30% rosin and 5% ethyl acetate.

### Example 9

A photovoltaic cell element 9 on which an electrode which was connected with a desired solder was produced in a similar manner to Example 8 except that the flax was changed from IPA containing 30% rosin and 5% ethyl acetate to IPA containing 12% rosin and 3% oxalic acid.

### Example 10

A photovoltaic cell element 10 on which an electrode which was connected with a desired solder was produced in a similar manner to Example 8 except that the flax was changed from IPA containing 30% rosin and 5% ethyl acetate to ethylene glycol containing 25% rosin and 1% formic acid.

### Example 11

A photovoltaic cell element 11 on which an electrode which was connected with a desired solder was produced in a similar manner to Example 8 except that the flax was changed from IPA containing 30% rosin and 5% ethyl acetate to IPA containing 20% rosin and 2% acetic acid.

### Example 12

A photovoltaic cell element 12 on which an electrode which was connected with a desired solder was produced in a similar manner to Example 1 except that the flax was changed from an aqueous hydrochloric acid solution containing 5% zinc chloride and 5% ammonium chloride to a glycerol solution hydrochloric acid containing 5% zinc chloride and 2% ammonium chloride (hydrochloride acid concentration 2%).

### Example 13

A photovoltaic cell element 13 on which an electrode which was connected with a desired solder was produced in a similar manner to Example 11 except that the heat treatment temperature of the paste composition Cu7PG1 for an electrode was changed from 660° C. to 550° C., and the flux was changed from IPA containing 20% rosin and 2% acetic acid to glycerin containing 20% rosin and 2% acetic acid.

### Example 14

A photovoltaic cell element 14 on which an electrode which was connected with a desired solder was produced in a similar manner to Example 13 except that the heat treatment temperature of the paste composition Cu7PG1 for an electrode was changed from 550° C. to 650° C.

### Example 15

A photovoltaic cell element 14 on which an electrode which was connected with a desired solder was produced in a similar manner to Example 13 except that, in place of the phosphorous-containing copper alloy particle containing 7% by mass of phosphorus Cu7PG1, a phosphorus-containing copper alloy particle containing 6% by mass of phosphorus (Cu6P) was used, and the heat treatment temperature of the paste composition for an electrode was changed from 550° C. to 580° C.

### Example 16

A photovoltaic cell element 16 on which an electrode which was connected with a desired solder was produced in a similar manner to Example 13 except that, in place of the phosphorous-containing copper alloy particle containing 7% by mass of phosphorus Cu7PG1, a phosphorus-containing copper alloy particle containing 8% by mass of phosphorus (Cu8P) was used, and the heat treatment temperature of the paste composition for an electrode was changed from 550° C. to 620° C.

### Example 17

A photovoltaic cell element 16 on which an electrode which was connected with a desired solder was produced in a similar manner to Example 13 except that, in place of the glass particle G1, a paste composition Cu7PG2 for an electrode using a glass particle (G2) which was adjusted as described below was used, and the heat treatment temperature of the paste composition for an electrode was changed from 550° C. to 600° C.

The glass particle G2 consisted of 45 parts of vanadium oxide (V₂O₅), 24.2 parts of phosphorus oxide (P₂O₅), 20.8 parts of barium oxide (BaO), 5 parts of antimony oxide (Sb₂O₃), and 5 parts of tungsten oxide (WO₃), and had a particle diameter (D50%) of 1.7 μm. The softening point of this glass was 492° C. and the crystallization temperature was 600° C. or higher.

### Example 18

A photovoltaic cell element 18 on which an electrode which was connected with a desired solder was produced in a similar manner to Example 17 except that, in place of the glass particle G2, a paste composition Cu7PG11 for an electrode using a glass particle (G11) which was adjusted as described below was used.

The glass particle G11 consisted of 3 parts of silicon dioxide (SiO₂), 60 parts of lead oxide (PbO), 18 parts of boron oxide (B₂O₅), 5 parts of bismuth oxide (Bi₂O₃), 5 parts of aluminum oxide (Al₂O₃), and 9 parts of zinc oxide (ZnO), and had a particle size (D50%) of 1.7 μm. The softening point of this glass was 420° C. and the crystallization temperature thereof was 600° C. or higher.

### Example 19

A photovoltaic cell element 19 on which an electrode which was connected with a desired solder was produced in a similar manner to Example 13 except that the heat treatment temperature of the paste composition for an electrode was changed from 550° C. to 600° C.

### Example 20

A photovoltaic cell element 20 on which an electrode which was connected with a desired solder was produced in a similar manner to Example 19 except that the temperature of the electrode when the flux was applied was changed from normal temperature to 150° C.

### Example 21

A photovoltaic cell element 21 on which an electrode which was connected with a desired solder was produced in a similar manner to Example 19 except that, when the flux was applied, only glycerin was applied first, and then, a glycerin containing 20 parts of rosin and 2 parts of acetic acid was applied.

### Example 22

A photovoltaic cell element 22 on which an electrode which was connected with a desired solder was produced in a similar manner to Example 19 except that, when the semiconductor substrate on which the solder coated tab wire had been disposed was placed on a hotplate to be heated to 250° C. while applying a pressing load on the tab wore, a constant temperature treatment at 150° C. for 10 minutes was added.

### Example 23

A photovoltaic cell element 33 on which an electrode which was connected with a desired solder was produced in a similar manner to Example 19 except that the solder with which the copper wire is coated was changed from Sn96.5Ag3Cu0.5 to Sn95Ag5.

### Example 24

A photovoltaic cell element 24 on which an electrode which was connected with a desired solder was produced in a similar manner to Example 19 except that the solder with which the copper wire is coated was changed from Sn96.5Ag3Cu0.5 to Sn95Sb5.

### Example 25

A photovoltaic cell element 25 on which an electrode which was connected with a desired solder was produced in a similar manner to Example 19 except that the solder with which the copper wire is coated was changed from Sn96.5Ag3Cu0.5 to Sn97Cu3.

### Example 26

A photovoltaic cell element 26 on which an electrode which was connected with a desired solder was produced in a similar manner to Example 19 except that the solder with which the copper wire is coated was changed from Sn96.5Ag3Cu0.5 to Bi58Sn42.

### Example 27

A photovoltaic cell element 27 on which an electrode which was connected with a desired solder was produced in a similar manner to Example 19 except that the solder with which the copper wire is coated was changed from Sn96.5Ag3Cu0.5 to In52Sn48.

### Example 28

A photovoltaic cell element 28 on which an electrode which was connected with a desired solder was produced in a similar manner to Example 2 except that the solder with which the copper wire is coated was changed from Sn96.5Ag3Cu0.5 to Sn63Pb37.

### Example 29

A photovoltaic cell element 29 on which an electrode winch was connected with a desired solder was produced in a similar manner to Example 2 except that the solder with which the copper wire is coated was changed from Sn96.5Ag3Cu0.5 to Sn50Pb50.

### Example 30

A photovoltaic cell element 30 on which an electrode winch was connected with a desired solder was produced in a similar manner to Example 2 except that the solder with which the copper wire is coated was changed from Sn96.5Ag3Cu0.5 to Sn62Pb36Ag2.

### Comparative Example 1

A photovoltaic cell element C1 was produced in a similar manner to Example 1 except that, in the composition for forming a power output electrode 135, the phosphorus-containing copper alloy particle Cu7P was changed to a silver particle (Ag), that the flux was changed from the aqueous hydrochloride acid solution containing 5 parts of zinc chloride and 5 parts of ammonium chloride to IPA containing 20 parts of rosin, and that the heat treatment of the paste composition for an electrode was changed from 600° C. to 800° C.

### Comparative Example 2

A photovoltaic cell element C32 was produced in a similiar manner to Example 1 except that the flux was changed from the aqueous hydrochloric acid solution containing 5 parts of zinc chloride and 5 parts of ammonium chloride to glycerin.

TABLE 1

| | Electrode | | | Flux | | | | | | | Solder |
|---|---|---|---|---|---|---|---|---|---|---|---|
| | | Treatment | | | Content | | Content | | Appli- | | Connect |
| | | Temper- | | Compo- | [% by | Compo- | [% by | | cation | Application | Heating |
| | Type | ature | Solder Type | nent A | mass] | nent B | mass] | Balance | Method | Temperature | Step |
| Exam- | Cu7PG1 | 600° C. | Sn96.5Ag3Cu0.5 | Zinc | 5 | Ammo- | 5 | Hydro- | One-time | Normal | Monotonous |
| ple 1 | | | | chloride | | nium | | chloric | appli- | temperature | heating |
| | | | | | | chloride | | acid | cation | | |
| | | | | | | | | water | | | |
| Exam- | Cu7PG1 | 600° C. | Sn96.5Ag3Cu0.5 | Hydrogen | 10 | — | — | BCA | One-time | Normal | Monotonous |
| ple 2 | | | | bromide | | | | | appli- | temperature | heating |
| | | | | acid | | | | | cation | | |
| Exam- | Cu7PG1 | 600° C. | Sn96.5Ag3Cu0.5 | Hydro- | 5 | — | — | Water | One-time | Normal | Monotonous |
| ple 3 | | | | chloric | | | | | appli- | temperature | heating |
| | | | | acid | | | | | cation | | |
| Exam- | Cu7PG1 | 600° C. | Sn96.5Ag3Cu0.5 | Zinc | 5 | Hydro- | 5 | Water | One-time | Normal | Monotonous |
| ple 4 | | | | chloride | | chloric | | | appli- | temperature | heating |
| | | | | | | acid | | | cation | | |
| Exam- | Cu7PG1 | 600° C. | Sn96.5Ag3Cu0.5 | Zinc | 5 | Ammo- | 2 | Terpin- | One-time | Normal | Monotonous |
| ple 5 | | | | chloride | | nium | | eol | appli- | temperature | heating |
| | | | | | | chloride | | | cation | | |
| Exam- | Cu7PG1 | 600° C. | Sn96.5Ag3Cu0.5 | Oxalic | 3 | Phenol | 6 | IPA | One-time | Normal | Monotonous |
| ple 6 | | | | acid | | resin | | | appli- | temperature | heating |
| | | | | | | | | | cation | | |
| Exam- | Cu7PG1 | 600° C. | Sn96.5Ag3Cu0.5 | Acetic | 2 | — | — | Glycerin | One-time | Normal | Monotonous |
| ple 7 | | | | acid | | | | | appli- | temperature | heating |
| | | | | | | | | | cation | | |
| Exam- | Cu7PG1 | 600° C. | Sn96.5Ag3Cu0.5 | Rosin | 30 | Ethyl | 5 | IPA | One-time | Normal | Monotonous |
| ple 8 | | | | | | acetate | | | appli- | temperature | heating |
| | | | | | | | | | cation | | |
| Exam- | Cu7PG1 | 600° C. | Sn96.5Ag3Cu0.5 | Rosin | 12 | Oxalic | 3 | IPA | One-time | Normal | Monotonous |
| ple 9 | | | | | | acid | | | appli- | temperature | heating |
| | | | | | | | | | cation | | |
| Exam- | Cu7PG1 | 600° C. | Sn96.5Ag3Cu0.5 | Rosin | 25 | Formic | 1 | Ethylene | One-time | Normal | Monotonous |
| ple 10 | | | | | | acid | | glycol | appli- | temperature | heating |
| | | | | | | | | | cation | | |
| Exam- | Cu7PG1 | 600° C. | Sn96.5Ag3Cu0.5 | Rosin | 20 | Acetic | 2 | IPA | One-time | Normal | Monotonous |
| ple 11 | | | | | | acid | | | appli- | temperature | heating |
| | | | | | | | | | cation | | |
| Exam- | Cu7PG1 | 600° C. | Sn96.5Ag3Cu0.5 | Zinc | 5 | Ammo- | 2 | Hydro- | One-time | Normal | Monotonous |
| ple 12 | | | | chloride | | nium | | chloric | appli- | temperature | heating |
| | | | | | | chloride | | acid, | cation | | |
| | | | | | | | | Glycerin | | | |
| Exam- | Cu7PG1 | 550° C. | Sn96.5Ag3Cu0.5 | Rosin | 20 | Acetic | 2 | Glycerin | One-time | Normal | Monotonous |
| ple 13 | | | | | | acid | | | appli- | temperature | heating |
| | | | | | | | | | cation | | |
| Exam- | Cu7PG1 | 650° C. | Sn96.5Ag3Cu0.5 | Rosin | 20 | Acetic | 2 | Glycerin | One-time | Normal | Monotonous |
| ple 14 | | | | | | acid | | | appli- | temperature | heating |
| | | | | | | | | | cation | | |
| Exam- | Cu6PG1 | 580° C. | Sn96.5Ag3Cu0.5 | Rosin | 20 | Acetic | 2 | Glycerin | One-time | Normal | Monotonous |
| ple 15 | | | | | | acid | | | appli- | temperature | heating |
| | | | | | | | | | cation | | |
| Exam- | Cu8PG1 | 620° C. | Sn96.5Ag3Cu0.5 | Rosin | 20 | Acetic | 2 | Glycerin | One-time | Normal | Monotonous |
| ple 16 | | | | | | acid | | | appli- | temperature | heating |
| | | | | | | | | | cation | | |
| Exam- | Cu7PG2 | 600° C. | Sn96.5Ag3Cu0.5 | Rosin | 20 | Acetic | 2 | Glycerin | One-time | Normal | Monotonous |
| ple 17 | | | | | | acid | | | appli- | temperature | heating |
| | | | | | | | | | cation | | |
| Exam- | Cu7PG11 | 600° C. | Sn96.5Ag3Cu0.5 | Rosin | 20 | Acetic | 2 | Glycerin | One-time | Normal | Monotonous |
| ple 18 | | | | | | acid | | | appli- | temperature | heating |
| | | | | | | | | | cation | | |
| Exam- | Cu7PG1 | 600° C. | Sn96.5Ag3Cu0.5 | Rosin | 20 | Acetic | 2 | Glycerin | One-time | Normal | Monotonous |
| ple 19 | | | | | | acid | | | appli- | temperature | heating |
| | | | | | | | | | cation | | |
| Exam- | Cu7PG1 | 600° C. | Sn96.5Ag3Cu0.5 | Rosin | 20 | Acetic | 2 | Glycerin | One-time | Normal | Monotonous |
| ple 20 | | | | | | acid | | | appli- | temperature | heating |
| | | | | | | | | | cation | | |
| Exam- | Cu7PG1 | 600° C. | Sn96.5Ag3Cu0.5 | Rosin | 20 | Acetic | 2 | Glycerin | Two-time | Normal | Monotonous |
| ple 21 | | | | | | acid | | | appli- | temperature | heating |
| | | | | | | | | | cation | | |
| Exam- | Cu7PG1 | 600° C. | Sn96.5Ag3Cu0.5 | Rosin | 20 | Acetic | 2 | Glycerin | One-time | Normal | Two-step |
| ple 22 | | | | | | acid | | | appli- | temperature | |
| | | | | | | | | | cation | | |
| Exam- | Cu7PG1 | 600° C. | Sn95Ag5 | Rosin | 20 | Acetic | 2 | Glycerin | One-time | Normal | Monotonous |
| ple 23 | | | | | | acid | | | appli- | temperature | heating |
| | | | | | | | | | cation | | |
| Exam- | Cu7PG1 | 600° C. | Sn95Sb5 | Rosin | 20 | Acetic | 2 | Glycerin | One-time | Normal | Monotonous |
| ple 24 | | | | | | acid | | | appli- | temperature | heating |
| | | | | | | | | | cation | | |
| Exam- | Cu7PG1 | 600° C. | Sn97Cu3 | Rosin | 20 | Acetic | 2 | Glycerin | One-time | Normal | Monotonous |
| ple 25 | | | | | | acid | | | appli- | temperature | heating |
| | | | | | | | | | cation | | |
| Exam- | Cu7PG1 | 600° C. | Bi58Sn42 | Rosin | 20 | Acetic | 2 | Glycerin | One-time | Normal | Monotonous |
| ple 26 | | | | | | acid | | | appli- | temperature | heating |
| | | | | | | | | | cation | | |
| Exam- | Cu7PG1 | 600° C. | In52Sn48 | Rosin | 20 | Acetic | 2 | Glycerin | One-time | Normal | Monotonous |
| ple 27 | | | | | | acid | | | appli- | temperature | heating |
| | | | | | | | | | cation | | |
| Exam- | Cu7PG1 | 600° C. | Sn63Pb37 | Hydrogen | 10 | — | — | BCA | One-time | Normal | Monotonous |
| ple 28 | | | | bromide | | | | | appli- | temperature | heating |
| | | | | acid | | | | | cation | | |
| Exam- | Cu7PG1 | 600° C. | Sn50Pb50 | Hydrogen | 10 | — | — | BCA | One-time | Normal | Monotonous |
| ple 29 | | | | bromide | | | | | appli- | temperature | heating |
| | | | | acid | | | | | cation | | |
| Exam- | Cu7PG1 | 600° C. | Sn62Pb36Ag2 | Hydrogen | 10 | — | — | BCA | One-time | Normal | Monotonous |
| ple 30 | | | | bromide | | | | | appli- | temperature | heating |
| | | | | acid | | | | | cation | | |
| Com- | AgG1 | 800° C. | Sn96.5Ag3Cu0.5 | Rosin | 20 | — | — | IPA | One-time | Normal | Monotonous |
| para- | | | | | | | | | appli- | temperature | heating |
| tive | | | | | | | | | cation | | |
| Exam- | | | | | | | | | | | |
| ple 1 | | | | | | | | | | | |
| Com- | Cu7PG1 | 600° C. | Sn96.5Ag3Cu0.5 | — | — | — | — | Glycerin | One-time | Normal | Monotonous |
| para- | | | | | | | | | appli- | temperature | heating |
| tive | | | | | | | | | cation | | |
| Exam- | | | | | | | | | | | |
| ple 2 | | | | | | | | | | | |

### <Evaluation>

The photovoltaic cell elements prepared were evaluated with a combination of WXS-155 S-10 manufactured by Wacom-Electric Co., Ltd. as artificial sunlight and a measurement device of I-V CURVE TRACER MP-160 (manufactured by EKI INSTRUMENT CO., LTD.) as a current-voltage (I-V) evaluation and measurement device. Each of the values measured for power generation performances as a photovoltaic cell are shown in Table 2 in terms of a relative value when the value measured in Comparative Example 1C was taken as 100.0. Eff (conversion efficiency), FF (fill factor), Voc (open voltage), and Jsc (short circuit current) indicating the power generation performances as a photovoltaic cell were obtained by carrying out the measurement in accordance with each of the JIS-C-8912, JIS-C-8913, and JIS-C-8914.

It is noted that, in Comparative Example 2, a power output electrode was not able to be connected to a tab wire, whereby evaluation was not available.

TABLE 2

| | Power Generation Performances | | | |
|---|---|---|---|---|
| | as Photovoltaic Cell | | | |
| | Eff (relative | | | Jsc (relative |
| | value) | FF (relative | Voc (relative | value) |
| | Conversion | value) | value) | Short-Circuit |
| Example | Efficiency | Fill Factor | Open voltage | Voltage |
| Example 1 | 97.6 | 99.6 | 96.1 | 99.5 |
| Example 2 | 97.7 | 98.3 | 98.0 | 100.4 |
| Example 3 | 96.8 | 97.1 | 97.9 | 99.4 |
| Example 4 | 96.2 | 95.5 | 95.8 | 98.9 |
| Example 5 | 98.6 | 96.4 | 94.4 | 95.4 |
| Example 6 | 101.8 | 98.6 | 98.0 | 98.3 |
| Example 7 | 97.8 | 98.3 | 100.0 | 97.6 |
| Example 8 | 101.4 | 99.1 | 97.6 | 102.3 |
| Example 9 | 101.6 | 101.1 | 101.3 | 101.4 |
| Example 10 | 101.3 | 103.2 | 101.4 | 103.0 |
| Example 11 | 100.1 | 102.1 | 99.3 | 101.7 |
| Example 12 | 96.3 | 96.2 | 98.6 | 96.0 |
| Example 13 | 96.1 | 97.4 | 96.2 | 95.7 |
| Example 14 | 102.9 | 102.5 | 101.9 | 102.0 |
| Example 15 | 99.7 | 100.1 | 98.3 | 100.2 |
| Example 16 | 100.6 | 101.9 | 100.9 | 102.2 |
| Example 17 | 103.3 | 100.1 | 102.0 | 102.0 |
| Example 18 | 99.8 | 99.5 | 98.9 | 102.1 |
| Example 19 | 97.6 | 99.7 | 99.1 | 99.1 |
| Example 20 | 99.0 | 100.1 | 98.8 | 98.4 |
| Example 21 | 101.3 | 100.3 | 102.0 | 100.6 |
| Example 22 | 100.6 | 100.1 | 99.2 | 99.8 |
| Example 23 | 101.3 | 101.0 | 100.4 | 99.4 |
| Example 24 | 101.4 | 98.6 | 100.6 | 102.0 |
| Example 25 | 97.6 | 99.4 | 98.6 | 98.5 |
| Example 26 | 99.5 | 97.3 | 98.5 | 100.9 |
| Example 27 | 98.2 | 96.4 | 97.6 | 100.1 |
| Example 28 | 99.7 | 101.9 | 101.8 | 101.7 |
| Example 29 | 101.0 | 100.3 | 98.8 | 99.5 |
| Example 30 | 102.2 | 101.8 | 99.8 | 102.1 |
| Comparative | 100.0 | 100.0 | 100.0 | 100.0 |
| Example 1 | | | | |
| Comparative | — | — | — | — |
| Example 2 | | | | |

The performances of the photo voltaic cell elements produced in Examples 1 to 30 were nearly similar to or higher than that of the photovoltaic cell element produced in Comparative Example 1.

### Example 31

Using the paste composition Cu7PG1 for an electrode obtained in the above, a photovoltaic cell element 31 having the structure shown in FIG. 4A and FIG. 4B was prepared in the same manner as in Example 1.

When the thus obtained photovoltaic cell element was evaluated in the same manner as described above, the photovoltaic cell element was found to exhibit excellent properties in the same manner as described above.

### EXPLANATION OF REFERENCES

1 Cell water including p-type silicon substrate
2 Current collecting grid electrode
3 n-type semiconductor layer
4 Through-hole electrode
5 High-concentration doped layer
6 Back surface electrode
7 Back surface electrode
130 Semiconductor substrate
131 Diffusion layer
137 Anti-reflection layer
133 Light-receiving surface electrode
134 Current collecting electrode
125 Power output electrode
136 Electrode component diffusion layer

1. An element comprising:
a silicon substrate;
an electrode that is provided on the silicon substrate and that is a sintered product of a paste composition for an electrode, the paste composition comprising a phosphorus-containing copper alloy particle, a glass particle, a solvent and a resin; and
a solder layer comprising a flux, the solder layer being provided on the electrode.

2. The element according to claim 1, wherein the flux comprises at least one selected from a halide, an inorganic acid, an organic acid or rosin.

3. The element according to claim 2, wherein the halide is at least one selected from chloride or a bromide.

4. The element according to claim 2, wherein the inorganic acid comprises at least one selected from hydrochloric acid, hydrogen bromide acid, nitric acid, phosphoric acid or a boric acid.

5. The element according to claim 2, wherein the organic acid comprises carboxylic acid.

6. The element according to claim 5, wherein the carboxylic acid comprises at least one selected from formic acid, acetic acid or oxalic acid.

7. The element according to claim 2, wherein the flux comprises rosin at 5% by mass or higher.

8. The element according to claim 1, wherein the solder layer comprises tin at 42% by mass or higher.

9. The element for a photovoltaic cell comprising the element according to claim 1,
wherein the silicon substrate comprises an impurity diffusion layer to be pn-joined, and the electrode is provided on the impurity diffusion layer.

10. A photovoltaic cell comprising the element for a photovoltaic cell according to claim 9; and
a tab wire connected to a solder layer of an electrode of the element.
